(19) United States
(12) Patent Application Publication
(10) Pub. No.: US 2015/0351286 A1
(43) Pub. Date: Dec. 3, 2015

(54) ELECTRONIC APPARATUS COOLING SYSTEM

(71) Applicant: NEC CORPORATION, Tokyo (JP)

(72) Inventors: Hitoshi SAKAMOTO, Tokyo (JP); Minoru YOSHIKAWA, Tokyo (JP); Akira SHOUJIGUCHI, Tokyo (JP); Masaki CHIBA, Tokyo (JP); Kenichi INABA, Tokyo (JP); Arihiro MATSUNAGA, Tokyo (JP)

(73) Assignee: NEC CORPORATION, Tokyo (JP)

(21) Appl. No.: 14/649,172

(22) PCT Filed: Dec. 3, 2013
(86) PCT No.: PCT/JP2013/007070

§ 371 Date: Jun. 2, 2015

(30) Foreign Application Priority Data
Dec. 3, 2012 (JP) 2012-264433

(51) Int. Cl. H05K 7/20

(52) U.S. Cl. CPC H05K 7/20663

(57) ABSTRACT

The present invention includes: a heat receiving portion that receives heat generated by an electronic apparatus and causes a phase of a first heating medium to change from a liquid phase to a gas; a heat radiating portion that causes a phase of the first heating medium to change from the gas to the liquid and supplies the first heating medium to the heat receiving portion; and a compressor that raises a temperature of the first heating medium supplied from the heat receiving portion and supplies the first heating medium to the heat radiating portion.

### TECHNICAL FIELD

The present invention relates to a cooling system for recovering heat generated by an electronic apparatus. More particularly, the invention relates to an exhaust heat recovery structure that cools heat generated inside the electronic device, recovers the heat, and raises the temperature of the recovered heat, and a cooling system employing the structure.

### BACKGROUND ART

There is a growing need to recover and effectively use thermal energy. In addition, in recent years, the amount of information processing has been increasing. Data centers are increasing in which devices such as server devices used for the Internet, communication devices, fixed telephones, and IP (Internet Protocol) telephones are installed. In a server room of the data center, a large number of electronic apparatuses such as computers are installed. The amount of power consumed by the electronic apparatuses has been increasing, and the thermal energy exhausted from the apparatuses is huge.

Patent Literature 1 discloses a hot-water supply system that recovers exhaust heat of a data center, and warms city water via a heat pump. This method recovers thermal energy by circulating a refrigerant within a system configured by a heat exchanger, a compressor, and an expansion valve, which is the same configuration as an ordinary air conditioner. When it is intended to apply the method to a data center, there will be a need to collect heat from servers via blower fans or the like. In addition to the necessity of power for blower fans, a low temperature due to heat absorption from circulation air in the server room causes low efficiency. In addition, the recovered thermal energy is supplied to city water, so that the thermal energy diffuses easily, and supply temperature is also low. Furthermore, in the data center in which a lot of electronic apparatuses are aggregated, there is a problem of increasing cooling power. Not only recovering exhaust heat as unused energy, but also efficient cooling is important for the effective use of energy.

Patent Literature 2 discloses a structure that cools an electronic component such as a CPU (Central Processing Unit) by use of a refrigeration cycle configured by a compressor, an expansion means, and the like. This method enables efficient cooling by directly depriving heat of an electronic apparatus, but collected thermal energy is to radiate heat into outside air at a low temperature, and thus it is not a structure to use the thermal energy effectively.

### CITATION LIST

### Patent Literature

[PTL 1] Japanese Laid-open Patent Publication No. 2012-042105

[PTL 2] Japanese Laid-open Patent Publication No. 2010-002084

### SUMMARY OF INVENTION

### Technical Problem

When it is intended to effectively use thermal energy generated by electronic apparatuses aggregated in a data center, in Patent Literature 1, exhaust heat included in air circulating in a server room needs to be collected and brought to a heat pump by blower fans. In addition, in Patent Literature 2, in order to directly recover thermal energy from a heat source, there is a method to mount a refrigeration cycle on a device, but the recovered thermal energy is radiated to the outside, and is not used effectively.

The present invention has been accomplished for the purpose of solving the above problems, and its objective is to provide a cooling system capable of collecting thermal energy generated by an electronic apparatus to cool the electronic apparatus and to provide the recovered thermal energy at a high temperature.

### Solution to Problem

A cooling system of the present invention includes: a heat receiving portion that receives heat generated by an electronic apparatus and change a phase of a first heating medium from a liquid phase to a gas; a heat radiating portion that the phase of the first heating medium from the gas to the liquid and supplies the first heating medium to the heat receiving portion; and a compressor that raises the temperature of the first heating medium supplied from the heat receiving portion and supplies the first heating medium to the heat radiating portion.

### Advantageous Effects of Invention

According to the cooling system of the present invention, by efficiently collecting a large amount of thermal energy generated by electronic apparatuses the electronic apparatuses are cooled, and it is possible to provide the recovered thermal energy at a high temperature.

### BRIEF DESCRIPTION OF DRAWINGS

FIG. 1 is a diagram illustrating a cooling system for an electronic apparatus according to a first exemplary embodiment.

FIG. 2 is a diagram illustrating a cooling system for an electronic apparatus according to a second exemplary embodiment.

FIG. 3 is a diagram illustrating a cooling system for an electronic apparatus according to a third exemplary embodiment.

FIG. 4 is a diagram illustrating electronic apparatuses mounted on a server rack and a cooling system.

FIG. 5 is a diagram illustrating a heat receiving portion thermally connected with a heat generating component, and an electronic apparatus.

FIG. 6 is a diagram illustrating a heat receiving portion receiving heat from an electronic apparatus, and the electronic apparatus.

FIG. 7 is a diagram illustrating a plurality of server racks and a heat storage means installed in a data center.

FIG. 8 is a diagram illustrating a cooling system for collecting heat from a plurality of racks and raising a temperature, and a data center.

FIG. 9 is a state diagram of a first heating medium.

FIG. 10 is a diagram illustrating physical properties of heat storage materials.

### DESCRIPTION OF EMBODIMENTS

Exemplary embodiments of the present invention will be hereinafter described in detail with reference to the drawings. However, the exemplary embodiments described below include limitations which are technically preferable to execute the present invention, but is not intended to limit the scope of the invention to below.

### First Exemplary Embodiment

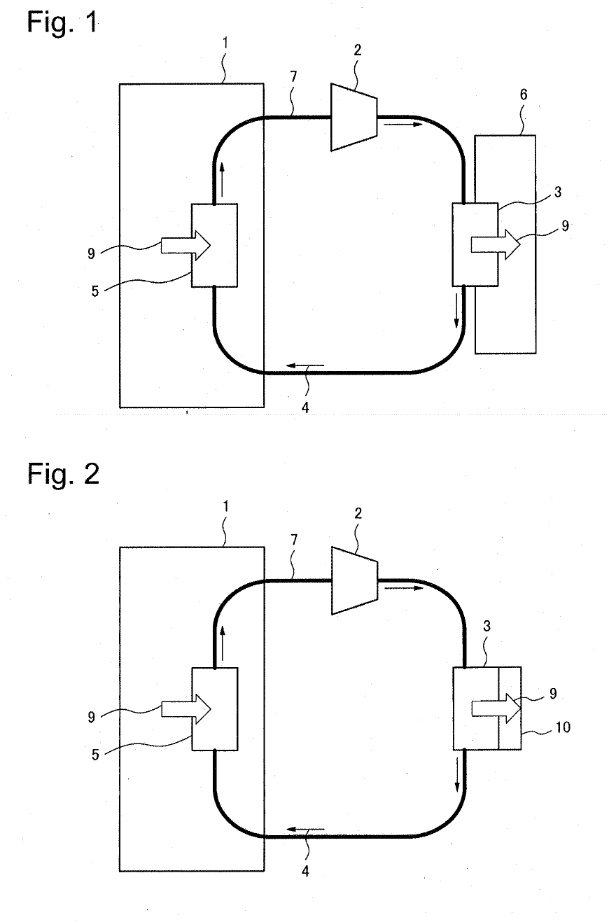

A first exemplary embodiment according to the present invention will be described. A cooling system according to the exemplary embodiment is illustrated in FIG. 1. In the exemplary embodiment, the cooling system that includes a heat receiving portion 5, a compressor 2, a heat radiating portion 3, and a first heating medium 4 circulating inside a piping 7, is configured such that the heat receiving portion 5 is installed so as to receive heat from an electronic apparatus 1, the heat radiating portion 3 is thermally connected with a heat storage means 6, and the heat storage means 6 receives thermal energy 9.

By receiving at the heat receiving portion 6 the thermal energy 9 generated by the electronic apparatus, it becomes possible to efficiently recover the thermal energy 9 from the electronic apparatus while cooling the electronic apparatus that is a heat source. The first heating medium 4 that receives heat at the heat receiving portion changes a phase from a liquid to a gas due to the received heat. The first heating medium 4 that has changed to the gas becomes high-temperature steam by interposing the compressor 2.

The heat radiating portion 3 is thermally connected with the heat storage means 6, and it is possible to store the thermal energy 9 that the first heating medium 4 has at a high temperature. By radiating heat, the condensed first heating medium becomes a liquid, and refluxes to the heat receiving portion 5. The heat receiving portion, the compressor, and the heat radiating portion of the cooling system are connected with each other by the piping 7, and the first heating medium 4 is kept in the inside in an airtight state.

When fluorocarbon or hydrofluoroether is used as the heating medium 4, it is preferable that the internal pressure at normal temperature is the saturated vapor pressure of those media. Consequently, at the heat receiving portion 5 that receives heat from the electronic apparatus 1, the first heating medium 4 is heated, and evaporates and vaporizes. On the other hand, at the heat radiating portion, the first heating medium 4 radiates heat to the heat storage means, and thereby condenses and liquefies.

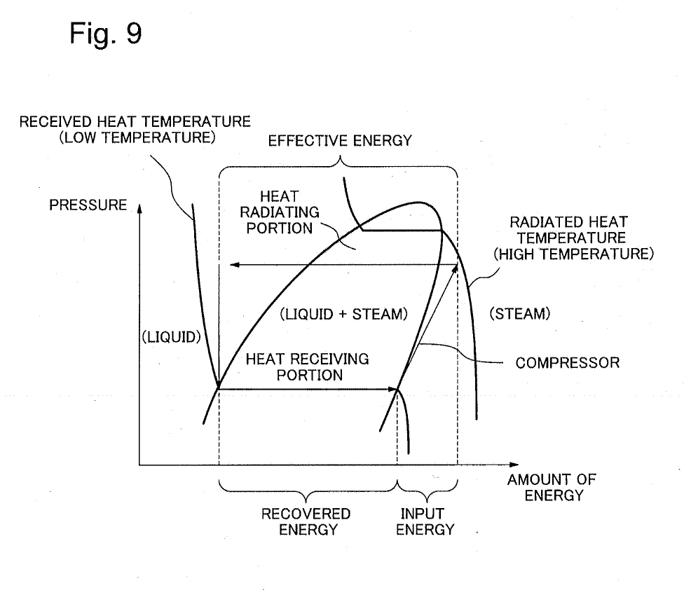

The compressor 2 compresses the first heating medium 4 in a vaporous state generated at the heat receiving portion 5, to thereby raise its temperature. The energy given by the compressor 2 is stored in the first heating medium 4 as internal energy, and becomes a part of effectively usable thermal energy. FIG. 9 illustrates a state in which the first heating medium 4 changes a phase in response to the amount of energy. Arrows indicate state changes of the first heating medium that circulates inside the cooling system of the exemplary embodiment. The heating medium 4 that changed a phase from a liquid to a gas by the thermal energy 9 recovered by the heat receiving portion 5 becomes high-temperature steam by energy put in by the compressor. In this case, the energy put in by the compressor 2 is smaller than the recovered energy. The steam that interposes the compressor 2 raises a temperature along with a pressure increase, and is compressed until the temperature reaches a desired temperature.

For example, when the thermal energy is recovered at 45° C. by use of hydrofluoroether, by compressing the density of the steam that comes out of the heat receiving portion to about ⅙, it is possible to raise the temperature to 100° C. In this case, the amount of energy required to be put in by the compressor is about 1/7 of the recovered energy. The thermal energy of high-temperature steam is stored in heat storage material as effective energy at a high temperature by heat radiation at the heat radiating portion.

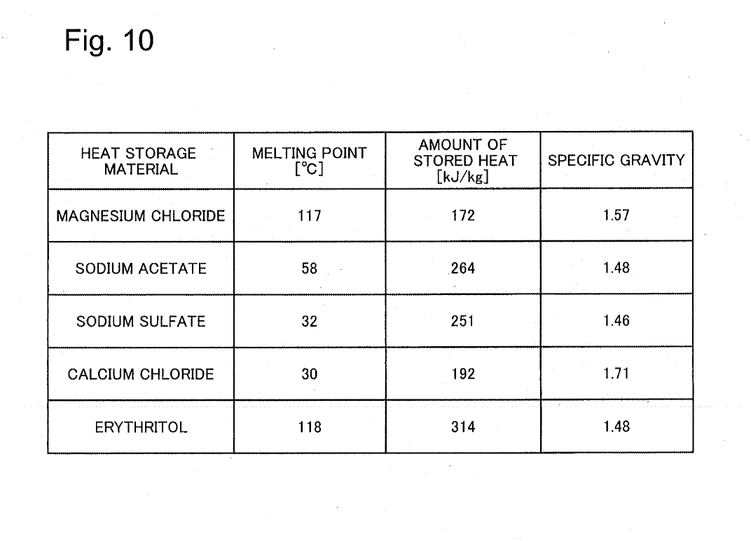

As for the heat storage means 6, it is preferable to use heat storage material thermally connected with the heat radiating portion. The heat storage material preferably has a large heat storage quantity per unit mass. As illustrated in FIG. 10, the heat storage material may be magnesium chloride, sodium acetate, sodium sulfate, calcium chloride, erythritol or the like. In the exemplary embodiment, a temperature at the heat radiating portion is raised by providing the compressor in the cooling system. Accordingly, such a material with a high melting point as magnesium chloride, erythritol or the like is more preferable as the heat storage material. The thermal energy stored at a temperature of 100° C. or more is versatile, and can be used for hot-water supply and the like.

When the above-described cooling system of the exemplary embodiment is used in a data center, the cooling system has an effect on reducing or eliminating an air-conditioning load.

### Second Exemplary Embodiment

A second exemplary embodiment according to the present invention will be described. A cooling system according to the exemplary embodiment is illustrated in FIG. 2. In the exemplary embodiment, in the cooling system including the heat receiving portion 5, the compressor 2, the heat radiating portion 3, and the first heating medium 4 that circulates inside, the heat receiving portion 5 is installed so as to receive heat from the electronic apparatus 1, and the heat radiating portion is thermally connected with a thermoelectric conversion means 10. By thermally connecting the heat radiating portion 3 with the thermoelectric conversion means, it is possible to convert the thermal energy 9 into electric energy. The thermoelectric conversion means may be a thermoelectric conversion element. The thermoelectric conversion means may be connected with a storage battery via a power conversion device.

### Third Exemplary Embodiment

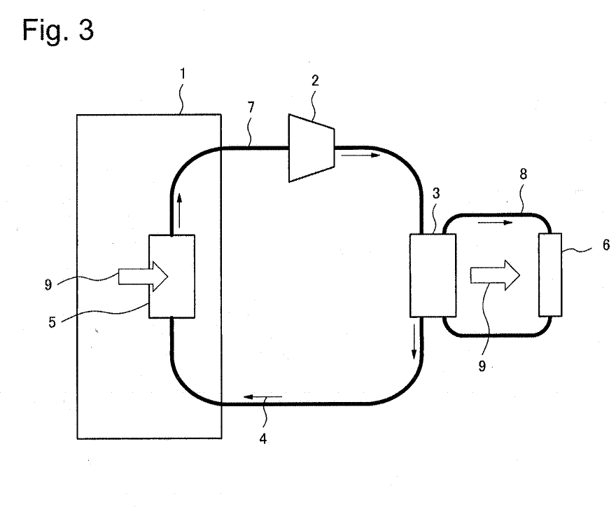

A third exemplary embodiment according to the present invention will be described. A cooling system according to the exemplary embodiment is illustrated in FIG. 3. In the exemplary embodiment, in the cooling system including the heat receiving portion 5, the compressor 2, the heat radiating portion 3, and the first heating medium 4 and a second heating medium 8 that circulate inside, the second heating medium is installed so as to transfer heat from the heat radiating portion to the heat storage means 6. The second heating medium may be, for example, water. By connecting the heat radiating portion with the heat storage means via the second heating medium, it is also preferable that a plurality of cooling systems of the invention can be connected with a large-scale heat storage tank.

### Fourth Exemplary Embodiment

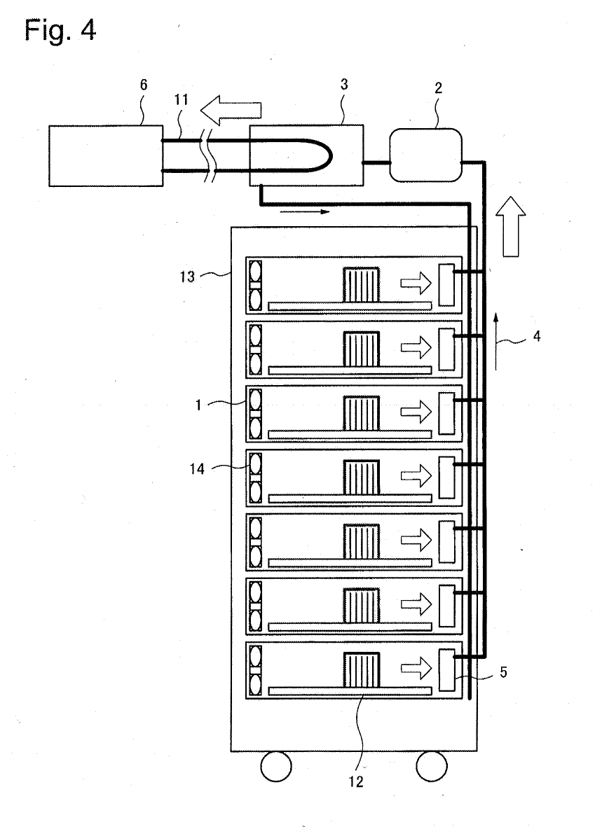

A fourth exemplary embodiment according to the present invention will be described. A cooling system according to the exemplary embodiment is illustrated in FIG. 4. In the exemplary embodiment, electronic apparatuses 1 are provided on a rack-shape shelf 13, and heat receiving portion or portions 5 are provided so as to receive heat from the electronic apparatuses. The heat receiving portion 5 may be divided and installed to fit servers 1 mounted on the rack. By installing the heat receiving portions so as to fit the servers, it is possible to directly recover generated heat, to collect heat from a plurality of servers, and to recover more heat.

The vaporized first heating medium 4 is collected and turned into high-temperature steam via a compressor 2. Thermal energy in the form of the high-temperature steam is transported to a heat storage material 6 of the heat storage means via the heat radiating portion 3. As illustrated in FIG. 4, the heat radiating portion 3 may have a structure of transferring the thermal energy to the heat storage material 6 via a heat transfer means 11.

When the heat receiving portions 5 in the exemplary embodiment are provided along one surface of the server rack, a plurality of heat receiving portions 5 are arranged vertically in the gravity direction. In order to evenly reflux the liquid to the respective heat receiving portions, it is effective to use a control valve or employ a structure by the use of gravity.

When the first heating medium is naturally circulated by the use of gravity, it is also preferable to provide a refrigerant buffer in each heat receiving portion. The first heating medium in a liquid form that refluxes to the heat receiving portion is temporarily stored in the tank-shaped buffer just before the heat receiving portion, and the first heating medium is supplied so that the amount of the first heating medium corresponds to the altitude of liquid level inside the heat receiving portion.

### Fifth Exemplary Embodiment

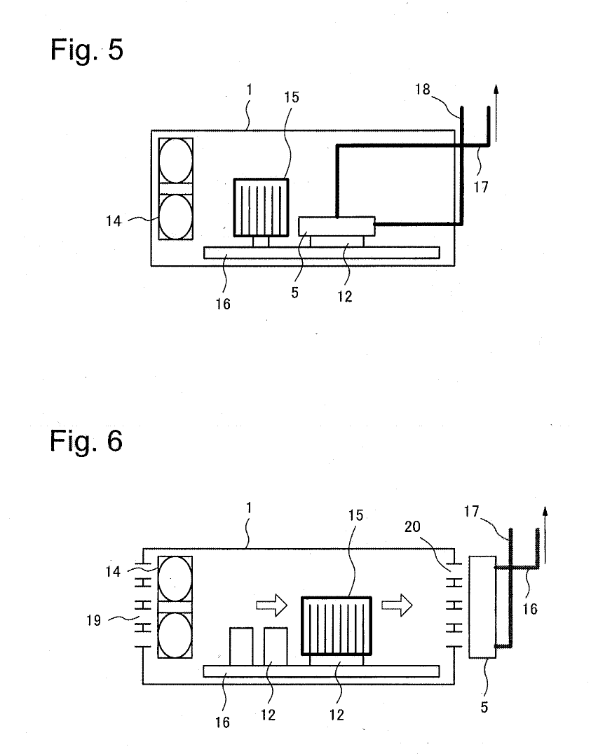

A fifth exemplary embodiment according to the present invention will be described. A heat receiving portion of a cooling system according to the exemplary embodiment and an electronic apparatus are illustrated in FIG. 5. In the exemplary embodiment, the heat receiving portion 5 is directly installed on a heat generating component 12 on a board 16 inside the electronic apparatus 1. As illustrated in FIG. 5, by installing the heat receiving portion 5 on the dominant heat generating component 12 inside the apparatus, it is possible to recover energy via a heating medium (steam) 17 and a heating medium (liquid) 18. There may be a plurality of heat generating components on which heat receiving portions are installed.

### Sixth Exemplary Embodiment

A sixth exemplary embodiment according to the present invention will be described. The heat receiving portion 5 of a cooling system according to the exemplary embodiment and the electronic apparatus 1 such as a sever device are illustrated in FIG. 6. The heat receiving portion may be installed outside of a server exhaust port 20. Also in this case, by providing the heat receiving portion inside a rack in which the server is mounted, it is possible to recover heat generated by the server efficiently. A fan 14 may be provided near an inlet port 19 as in FIG. 5, or may be provided near an exhaust port.

### Seventh Exemplary Embodiment

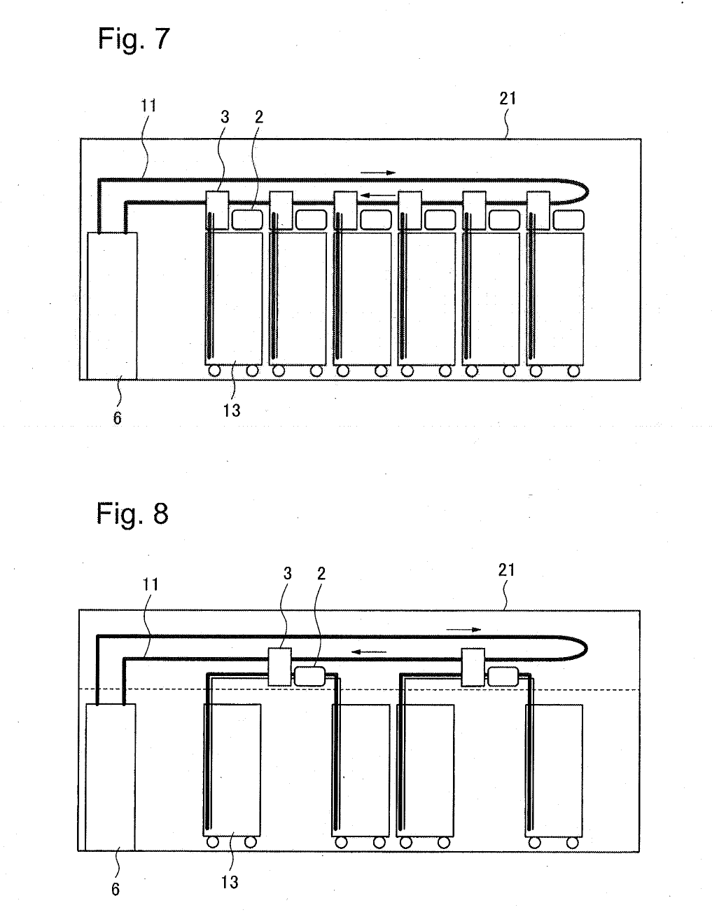

A seventh exemplary embodiment according to the present invention will be described. A data center 21 provided with a cooling system according to the exemplary embodiment is illustrated in FIGS. 7 and 8. As illustrated in FIG. 7, each rack 13 is provided with the cooling system that includes the compressor 2 and the heat radiating portion 3 of the exemplary embodiment, and the cooling system receives heat from an electronic apparatus mounted on the rack 13. Thermal energy from each heat radiating portion is transported as far as a heat storage tank 6 via the heat transfer means 11. The heat transfer means may include a piping connecting respective heat radiating portions, the second heating medium 8 flowing inside, and a pump circulating the second heating medium. In addition, as illustrated in FIG. 8, a pair of the compressor 2 and the heat radiating portion 3 may be provided for a plurality of racks.

The present invention claims the preferential right based on Japanese Patent Application No. 2012-264433, filed on Dec. 3, 2012 which is incorporated herein in its entirety.

### INDUSTRIAL APPLICABILITY

The present invention relates to an exhaust heat recovery structure that cools heat generated inside an electronic apparatus, recovers the heat, and raises the temperature of the recovered heat, and a cooling system employing the structure.

### REFERENCE SIGNS LIST

1 Electronic apparatus
2 Compressor
3 Heat radiating portion
4 First heating medium
5 Heat receiving portion
6 Heat storage means
7 Piping
8 Second heating medium
9 Thermal energy
10 Thermoelectric conversion means
11 Heat transfer means
12 Heat generating component
13 Rack
14 Fan

1. A cooling system comprising:
a heat receiving portion [means for] receiving heat generated by an electronic apparatus and changing a phase of a first heating medium from a liquid phase to a gas phase;
a heat radiating portion [means for] changing the phase of the first heating medium from the gas to the liquid and supplying the first heating medium to the heat receiving portion [means]; and
a compressor [for] raising the temperature of the first heating medium supplied from the heat receiving portion [means] by compressing the first heating medium in the gas phase and supplying the first heating medium to the heat radiating portion [means].

2. The cooling system according to claim 1 including a heat utilizing portion [means for] utilizing exhaust heat from the heat radiating portion [means] as a heat source.

3. The cooling system according to claim 2 wherein the heat utilizing portion [means] includes a heat storage portion [means for] storing heat from the heat radiating portion [means].

4. The cooling system according to claim 2 wherein the heat utilizing portion [means] includes a thermoelectric conversion portion [means for] receiving heat from the heat radiating portion [means].

5. The cooling system according to claim 2 wherein the heat utilizing portion [means] includes a portion [means for] transferring heat to a second heating medium receiving heat from the heat radiating portion [means].

6. The cooling system according to claim 3 [any one of claims 3 to 5] including a heat transfer portion [means] between the heat radiating portion [means] and the heat utilizing portion [means].

7. The cooling system according to claim 1 wherein the heat receiving portion [means] receives exhaust heat from the electronic apparatus.

8. The cooling system according to claim 1 wherein regarding the heat receiving portion [means], a plurality of heat receiving portion [means] are provided in response to the number of the electronic apparatuses.

9. The cooling system according to claim 7 wherein the heat receiving portion [means] is provided on a server device or a network device or in a rack in which those devices are mounted.

10. The cooling system according to claim 9 wherein regarding the rack, a plurality of racks are installed in a data center.
